(19) United States
(12) Patent Application Publication
(10) Pub. No.: US 2015/0200094 A1
(43) Pub. Date: Jul. 16, 2015

(54) CARBON FILM STRESS RELAXATION

(71) Applicant: APPLIED MATERIALS, INC., Santa Clara, CA (US)

(72) Inventors: Brian Saxton Underwood, Campbell, CA (US); Abhijit Basu Mallick, Fremont, CA (US)

(73) Assignee: APPLIED MATERIALS, INC., Santa Clara, CA (US)

(21) Appl. No.: 14/152,101

(22) Filed: Jan. 10, 2014

(51) Int. Cl. H01L 21/033; C23C 14/34

(52) U.S. Cl. CPC H01L 21/0337; C23C 14/3471

(57) ABSTRACT

Methods are described for treating a carbon film on a semiconductor substrate. The carbon may have a high content of sp3 bonding to increase etch resistance and enable new applications as a hard mask. The carbon film may be referred to as diamond-like carbon before and even after treatment. The purpose of the treatment is to reduce the typically high stress of the deposited carbon film without sacrificing etch resistance. The treatment involves ion bombardment using plasma effluents formed from a local capacitive plasma. The local plasma is formed from one or more of inert gases, carbon-and-hydrogen precursors and/or nitrogen-containing precursors.

### FIELD

Embodiments of the invention relate to treating a carbon film on a semiconductor substrate in embodiments.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers or thinning lateral dimensions of features already present on the surface. Often it is desirable to have an etch process which etches one material faster than another helping e.g. a pattern transfer process proceed. Such an etch process is said to be selective of the first material. During a pattern transfer process an etch process must be selective of the material to be patterned, while avoiding significant removal of the patterned overlying resist material. The patterned overlying resist material is often referred to as a mask.

Hardmask layers like silicon nitride are used as more resilient masks than traditional polymer or other organic “soft” resist materials. Increased resilience of hardmasks opens new processing pathways by increasing selectivities and the breadth of selectively etchable materials. Patterned hardmask layers also tend to display less line-edge roughness than soft resist materials.

Advanced Pattern Film (APF™, Applied Materials, Santa Clara, Calif.) is an example of a carbon-based hardmask material which further expands selectivity options for semiconductor processing flow sequences. Diamond-like carbon films (DLC) may be created having a significantly increased proportion of sp³ bonding which even further enhances etch selectivity of a variety of materials relative to hardmask DLC carbon films. However, DLC films possess high stress as-deposited which can distort or destroy patterned features once the DLC film is patterned. Methods are needed to treat DLC carbon films such that etch selectivity is kept high but the stress of the deposited film is significantly reduced.

### BRIEF SUMMARY

Methods are described for treating a carbon film on a semiconductor substrate. The carbon may have a high content of sp³ bonding to increase etch resistance and enable new applications as a hard mask. The carbon film may be referred to as diamond-like carbon before and even after treatment. The purpose of the treatment is to reduce the typically high stress of the deposited carbon film without sacrificing etch resistance. The treatment involves ion bombardment using plasma effluents formed from a local capacitive plasma. The local plasma is formed from one or more of inert gases, carbon-and-hydrogen precursors and/or nitrogen-containing precursors.

Embodiments of the invention include methods of treating a carbon film on a semiconductor substrate. The methods include transferring the semiconductor substrate onto a substrate pedestal in a substrate processing region. The methods further include flowing an inert gas into the substrate processing region. The methods further include applying capacitive power between the substrate pedestal and a parallel conducting plate. The methods further include forming a plasma from the inert gas within the substrate processing region. The methods further include sputtering the carbon film to form a reduced-stress carbon film.

Embodiments of the invention include methods of treating a carbon film on a semiconductor substrate. The methods include transferring the semiconductor substrate onto a substrate pedestal in a substrate processing region. The methods further include flowing a carbon-and-hydrogen-containing precursor into the substrate processing region. The methods further include applying capacitive power between the substrate pedestal and a parallel conducting plate. The methods further include forming a plasma from the carbon-and-hydrogen-containing precursor within the substrate processing region. The methods further include implanting the carbon film to form a reduced-stress carbon film.

Embodiments of the invention include methods of treating a carbon film on a semiconductor substrate. The methods include transferring the semiconductor substrate onto a substrate pedestal in a substrate processing region. The methods further include flowing a nitrogen-containing precursor into the substrate processing region. The methods further include applying capacitive power between the substrate pedestal and a parallel conducting plate. The methods further include forming a plasma from the nitrogen-containing precursor within the substrate processing region to form plasma effluents. The methods further include implanting the carbon film with the plasma effluents to form a reduced-stress carbon film.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 is a flowchart illustrating selected steps for treating carbon films according to embodiments of the invention.

FIG. 2 is another flowchart illustrating selected steps for treating carbon films according to embodiments of the invention.

FIG. 3 is another flowchart illustrating selected steps for treating carbon films according to embodiments of the invention.

FIG. 4 shows a substrate processing system according to embodiments of the invention.

FIG. 5 shows a substrate processing chamber according to embodiments of the invention.

FIG. 6 shows a graph of film stress for untreated carbon films as well as carbon films treated according to embodiments of the invention.

### DETAILED DESCRIPTION

Methods are described for treating a carbon film on a semiconductor substrate. The carbon may have a high content of sp³ bonding to increase etch resistance and enable new applications as a hard mask. The carbon film may be referred to as diamond-like carbon before and even after treatment. The purpose of the treatment is to reduce the typically high stress of the deposited carbon film without sacrificing etch resistance. The treatment involves ion bombardment using plasma effluents formed from a local capacitive plasma. The local plasma is formed from one or more of inert gases, carbon-and-hydrogen precursors and/or nitrogen-containing precursors.

The initial deposition of carbon films with high sp³ bonding concentration tends to exhibit a high stress which can deform or destroy patterned features forming on a patterned substrate. Sputtering and/or ion implanting the carbon film, as described herein, has been found to decrease the stress without significantly decreasing the desirable sp³ bonding concentration. Without wishing to bind the claims to theoretical mechanisms which may or not be entirely correct, it is hypothesized that the treatments taught herein may remove weaker non-sp bonds and C—H bonds present in the carbon film. Some of the treatments are thought to increase the mass density and possibly the concentration of sp³ bonds as well. The decreased stress has been found to not decrease the etch resistance of the carbon films and, therefore, maintains their utility as a resilient hard mask alternative to traditional hard masks. Sputtering and ion implantation of carbon films as taught herein may form reduced-stress carbon films while maintaining high etch resistance of the treated carbon films to a variety of gas-phase etchants typically used to remove silicon oxide, silicon nitride and silicon films.

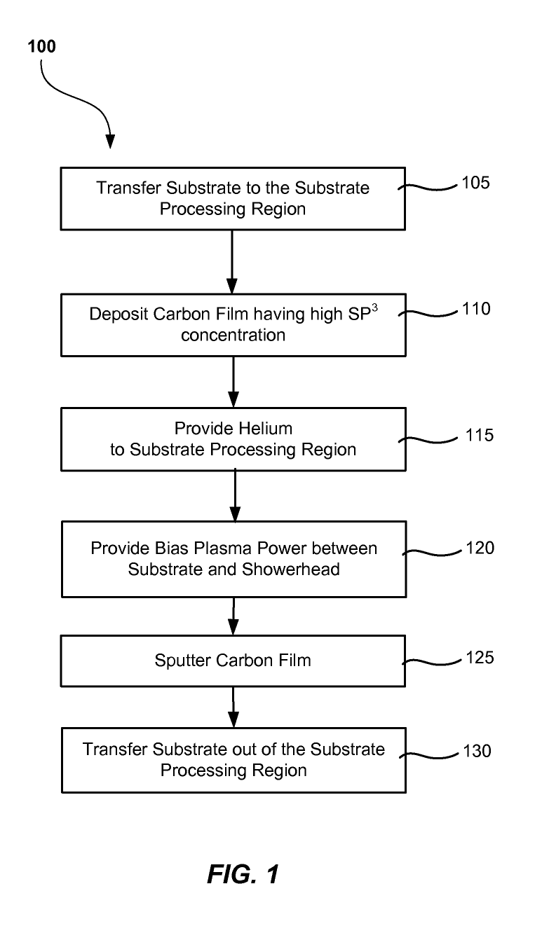

In order to better understand and appreciate the invention, reference is now made to FIG. 1 which is a flowchart illustrating selected steps in a method of treating a carbon film 100 on a substrate according to embodiments. The substrate is transferred into a substrate processing region (operation 105). A carbon film is formed 110 on the substrate and has a high concentration of sp³ bonding as is found in diamond and diamond-like carbon (DLC) films. The concentration of sp3 bonding for all films discussed herein may be greater than 25%, greater than 30%, greater than 40% or even greater than 50% according to embodiments. The carbon film may be deposited on the substrate prior to or after operation 105 in embodiments. Methods of forming diamond-like carbon films typically include exposure to a hydrocarbon and often another source of hydrogen (e.g. H₂). An excitation source such as a plasma or hot filament may be used to dissociate the precursors. Carbon sp³ bonding may be preferentially produced by scavenging sp² bonded carbon (graphitic carbon) during the growth process.

Helium is flowed into the substrate processing region (operation 115) and a bias plasma power is applied between a showerhead and the substrate and/or a substrate pedestal supporting the substrate (operation 120). The carbon film is sputtered with helium ions to treat the carbon film in operation 125). In general, an inert gas is flowed into the substrate processing region and the inert gas comprises one or more of helium, argon or neon according to embodiments. The substrate processing region may be essentially devoid of reactive species and consists of inert gases in embodiments. Sputtering with inert gases may preferentially remove weaker carbon bonds in the carbon film while retaining sp³ bonded carbon. The preferential removal of weaker bonds has been found to dramatically reduce the stress of the carbon film and facilitate its use as a hardmask. The term “sputtering” is used herein to describe a process where inert species are plasma-excited, ionized and accelerated toward the substrate at well-above thermal energies. Removal of a small concentration of carbon atoms undoubtedly occurs but is not necessarily the goal. Some inert species may be embedded in the film and the bonding structure among carbon atoms which remain in the film may be modified according to embodiments. The net effect of all these possibilities is an increase in etch resistance. The substrate is transferred out of the substrate processing region in operation 130.

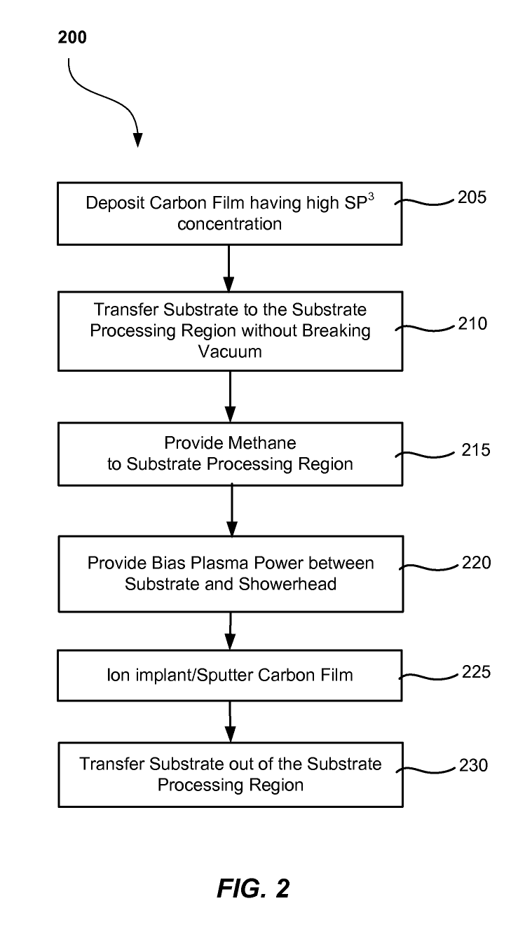

Reference is now made to FIG. 2 which is another flowchart illustrating selected steps in a method of treating a carbon film 200 on a substrate according to embodiments. A carbon film is formed 205 on the substrate and has a high concentration of sp³ bonding. The substrate is transferred into a substrate processing region (operation 210). The concentration of sp3 bonding, in embodiments, were provided previously. The carbon film may be deposited on the substrate prior to or after operation 210 in embodiments. Methane is flowed into the substrate processing region (operation 215) and a bias plasma power is applied between a showerhead and the substrate and/or a substrate pedestal supporting the substrate (operation 220). The carbon film is bombarded and implanted with ionized plasma effluents to treat the carbon film in operation 225. In general, a hydrocarbon or carbon-and-hydrogen-containing precursor is flowed into the substrate processing region and the carbon-and-hydrogen-containing precursor may consist of hydrogen and carbon according to embodiments. Exemplary carbon-and-hydrogen-containing precursors include methane, ethane and propane in embodiments. The substrate processing region may be essentially devoid of reactive species other than the carbon-and-hydrogen-containing precursor according to embodiments. Ion implanting with carbon-and-hydrogen-containing precursor plasma effluents may preferentially remove weaker carbon bonds in the carbon film while retaining sp³ bonded carbon. Ion implanting with the plasma effluents may also increase the density of the carbon film and may increase the concentration of sp3 bonded carbon in embodiments. The treatment has been found to dramatically reduce the stress of the carbon film and facilitate its use as a hardmask. The carbon film may be diamond-like carbon prior to treatment and the treated/reduced-stress carbon film may remain diamond-like carbon following the operation of implanting the carbon film in embodiments. The substrate is transferred out of the substrate processing region in operation 230. In the embodiments represented in both FIG. 1 and FIG. 2, the reduced-stress carbon film may consist of carbon and hydrogen in embodiments.

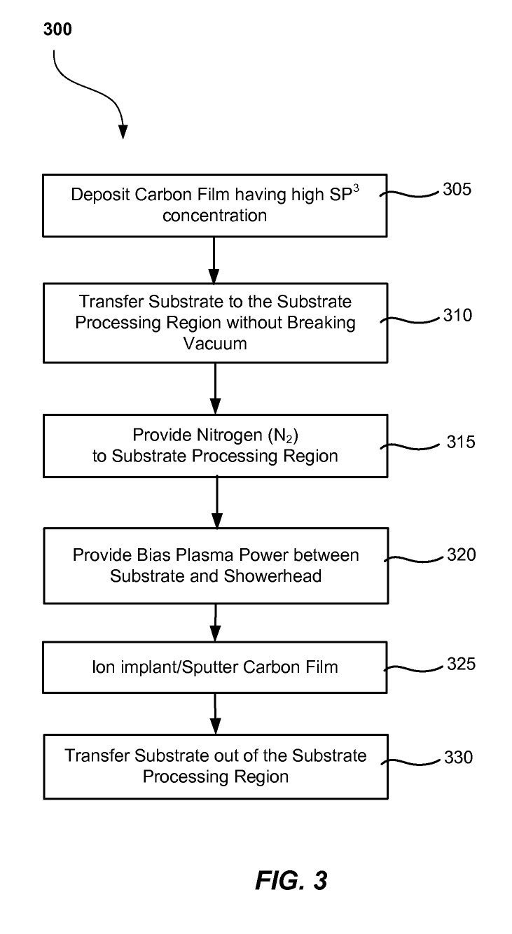

FIG. 3 is another flowchart illustrating selected steps in a method of treating a carbon film 300 on a substrate according to embodiments. A carbon film is formed 305 on the substrate and has a high concentration of sp bonding. The substrate is transferred into a substrate processing region (operation 310). The concentration of sp3 bonding, in embodiments, were provided previously. The carbon film may be deposited on the substrate prior to or after operation 310 in embodiments. Nitrogen (N₂) is flowed into the substrate processing region (operation 315) and a bias plasma power is applied between a showerhead and the substrate and/or a substrate pedestal supporting the substrate (operation 320). The carbon film is bombarded and implanted with ionized plasma effluents to treat the carbon film in operation 325. In general, a nitrogen-containing precursor is flowed into the substrate processing region and the nitrogen-containing precursor may consist of hydrogen and nitrogen according to embodiments. Exemplary nitrogen-containing precursors include nitrogen (N₂), ammonia and hydrazine in embodiments. The substrate processing region may be essentially devoid of reactive species other than the nitrogen-containing precursor according to embodiments. Ion implanting with nitrogen-containing precursor plasma effluents may preferentially remove weaker carbon bonds in the carbon film while retaining sp³ bonded carbon. Ion implanting with the plasma effluents may also increase the density of the carbon film and increase etch resistance of the treated/reduced-stress carbon film in embodiments. The treatment has been found to dramatically reduce the stress of the carbon film and facilitate its use as a hardmask. The substrate is transferred out of the substrate processing region in operation 330. The reduced-stress carbon film has some nitrogen content due to the bombardment with the nitrogen-containing plasma effluents. The nitrogen content may be between 5% and 20%, in embodiments, measured as an atomic percentage with the balance being carbon and hydrogen.

A bias plasma power is applied capacitively between two parallel plates to excite and direct ionized species toward the substrate in all the embodiments described herein. The plasma power may be applied as a radio-frequency oscillating voltage between the substrate support pedestal and a parallel conducting plate in the form of a showerhead in embodiments. The bias plasma power may be applied as a signal oscillating at between 300 kHz and 20 MHz or between 500 kHz and 10 MHz or between 1 MHz and 4 MHz according to embodiments. The bias plasma power may be greater than 500 watts, greater than 1000 watts or greater than 1500 watts according to embodiments. Higher ranges for bias plasma power may be used to increase the penetration depth of the sputtering/ion implantation treatment. A bias power of 500 watts, 1000 watts and 1500 watts were found to result in 5000 volts, 6900 volts and 8300 volts, respectively, as a peak-to-peak (p-p) oscillating voltage between the showerhead and the substrate support pedestal (a.k.a. substrate pedestal). A secondary “source” power may be used to increase ionization and may be applied inductively according to embodiments. The source plasma power may be significantly less than the bias plasma power since higher source plasma powers were found to result in higher stress treated carbon films. The source plasma power may be between 0 watts and 1000 watts, between 0 watts and 500 watts or between 200 watts and 400 watts according to embodiments. Applying a non-zero plasma source power may lower the grounding sheath and may enable the use of higher bias plasma powers.

The pressure in the substrate processing region during treatment may be in the range from below 1 mTorr up to several hundred mTorr to balance the ion flux and mean free path. The treatment pressure in the substrate processing region may be between 1 mTorr and 200 mTorr, between 2 mTorr and 100 mTorr, between 3 mTorr and 40 mTorr, between 4 mTorr and 20 mTorr or between 5 mTorr and 10 mTorr according to embodiments.

Treatments described herein (sputtering/bombardment/ion implantation) of the carbon films may remove graphitic carbon from the carbon film to reduce the stress of a compressive carbon film to form a reduced-stress carbon film. The treatments may be applied cyclically, after each layer of a thick multi-layer carbon film, since the treatments have depth penetration limits. A completed reduced-stress multi-layer carbon film may be greater than or about 100 Å, greater than or about 200 Å, greater than or about 500 Å, greater than or about 1000 Å, greater than or about 2000 Å, greater than or about 5000 Å or greater than or about 10,000 Å according to embodiments. Treatment may performed once deposition is complete for some thicknesses or for a single layer of a multi-layer carbon film. Carbon films may be between about 25 Å and about 1500 Å, between about 25 Å and about 1000 Å, between about 25 Å and about 500 Å, between about 25 Å and about 300 Å, or between about 25 Å and about 150 Å in embodiments.

The sputtering and ion implantation may be carried out at within similar substrate temperature ranges in embodiments. For example, the substrate may be about 300° C. or less, about 250° C. or less, about 200° C. or less, about 150° C. or less according to embodiments. The temperature of the substrate may be about −10° C. or more, about 50° C. or more, about 100° C. or more, about 125° C. or more, about 150° C. or more in embodiments. Upper limits may be combined with suitable lower limits in embodiments. The duration of the treatments described herein may be applied for more than thirty seconds, more than one minute or more than two minutes in embodiments.

Avoiding substrate exposure to atmospheric conditions between deposition and treatment may be avoided during any of the sputtering/ion implantation techniques described herein by performing deposition and ion implantation in the same processing chamber or on the same processing system. Exposure to atmospheric conditions may also be avoided by transferring the substrate from one system to another in transfer pods equipped with inert gas environments.

In some embodiments, a deposition chamber may be equipped with an in-situ plasma generating system to perform plasma ion implantation in the substrate processing region of the deposition chamber. This allows the substrate to remain in the same substrate processing region for both deposition and ion implantation, enabling the substrate to avoid exposure to atmospheric conditions between deposition and implant. Alternately, the substrate may be transferred to a sputtering/ion implantation unit in the same fabrication system without breaking vacuum and/or being removed from system. The carbon film and reduced-stress carbon films formed using the methods presented herein may have high etch resistance to gas phase etch processes commonly used for silicon (e.g. polysilicon), silicon oxide and silicon nitride. Carbon films having a preponderance of sp³ bonding (either before or after treatments described herein) may display substantially no etch rate in standard dry dielectric etches, including for example gas phase etching using chlorine or bromine.

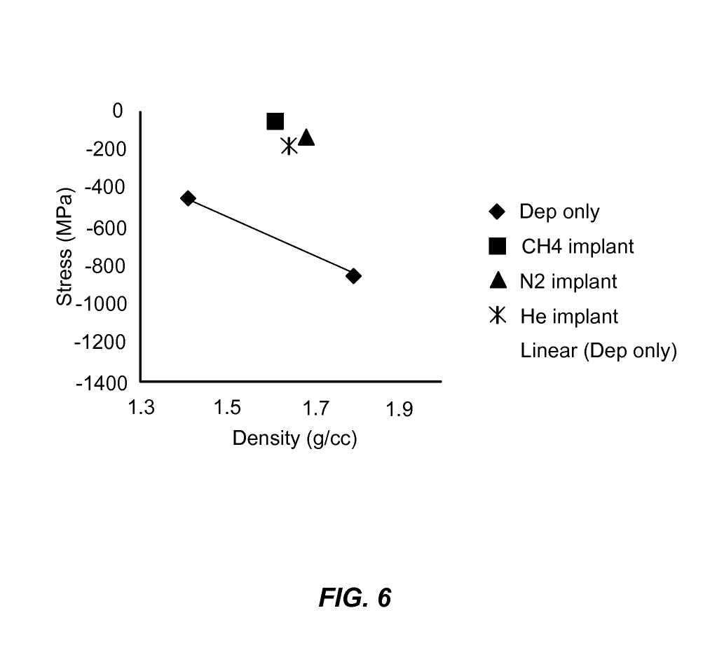

The reduced-stress carbon films formed using the methods described herein may have a film stress less than 200 MPa. Prior to treatment, the carbon films may have a film stress greater than 400 MPa and up to 10,000 MPa. The untreated carbon films may have a film stress greater than 400 MPa, greater than 750 MPa, greater than 1 GPa, or greater than 3 GPa according to embodiments. FIG. 6 shows pre-treatment carbon films as well as films treated with each embodiment described in connection with FIGS. 1-3.

The flows of methane, nitrogen and helium were 70 sccm into the substrate processing region and the processing pressure was between 5 mTorr and 10 mTorr. A bias plasma power of between 1000 watts and 2000 watts was used in each case with a 2 MHz RF voltage. The film thickness was 100 Å in each case. The methane treatment reduced the density slightly from 1.68 g/cm³ to 1.61 g/cm³ but decreased the compressive film stress from 685 MPa to 71 MPa. The nitrogen treatment did not alter the density but decreased the compressive film stress from 685 MPa to 143 MPa. The helium treatment also did not alter the density but decreased the compressive film stress from 685 MPa to 157 MPa. Argon was also tested but only decreased the film stress to 432 MPa while leaving the density substantially the same. The films had relatively low sp3 content and the advantages were found to be even more impressive for high sp3 concentration carbon films. Reduced-stress carbon films created using the methods taught herein may have a magnitude of stress (either compressive or tensile) which is less than 250 MPa, less than 200 MPa, less than 150 MPa, or preferably less than 100 MPa according to embodiments.

Additional process parameters and other aspects will be presented in the course of describing an exemplary carbon film implant system according to embodiments.

### Exemplary Carbon Film Implant System

Implant chambers that may implement embodiments of the present invention may include capacitive local plasma chambers. Specific examples of implant systems that may implement embodiments of the invention include the plasma immersion ion implant chamber (P3I) chambers/systems available from Applied Materials, Inc. of Santa Clara, Calif.

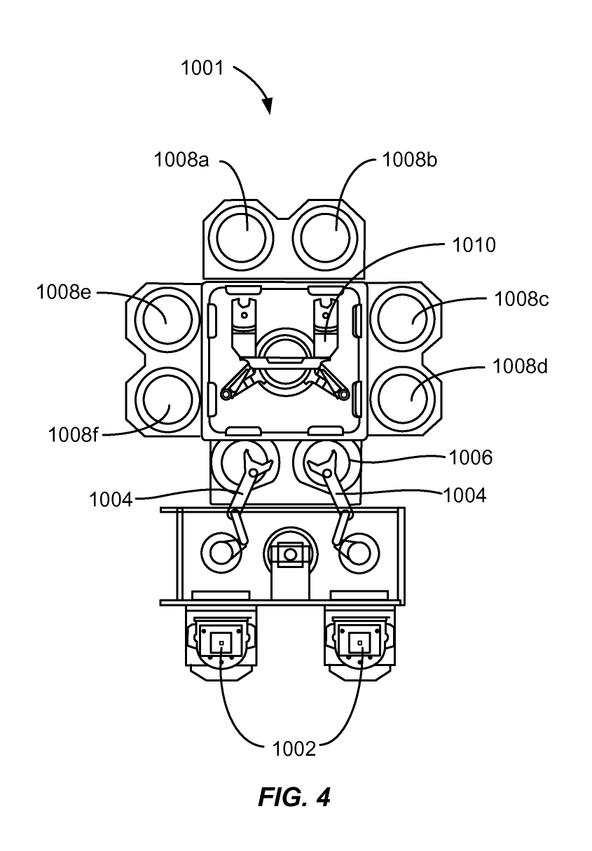

Embodiments of the implant systems may be incorporated into larger fabrication systems for producing integrated circuit chips. FIG. 4 shows an exemplary substrate processing system 1001 of deposition, implanting, baking and curing chambers according to disclosed embodiments. In the figure, a pair of FOUPs (front opening unified pods) 1002 supply substrate substrates (e.g., 300 mm diameter wafers) that are received by robotic arms 1004 and placed into a low pressure holding area 1006 before being placed into one of the wafer processing chambers 1008a-f. A second robotic arm 1010 may be used to transport the substrate wafers from the holding area 1006 to the processing chambers 1008a-f and back.

The processing chambers 1008a-f may include one or more system components for depositing, implanting, curing and/or etching a carbon film on the substrate wafer. In one configuration, two pairs of the processing chamber (e.g., 1008c-d and 1008e-f) may be used to deposit the carbon film on the substrate, and the third pair of processing chambers (e.g., 1008a-b) may be used to implant the deposited carbon film. In another configuration, the processing chambers (1008c-f) may be configured to both deposit and implant a carbon film on the substrate. Any one or more of the processes described may be carried out on chamber(s) separate from the fabrication system shown in embodiments.

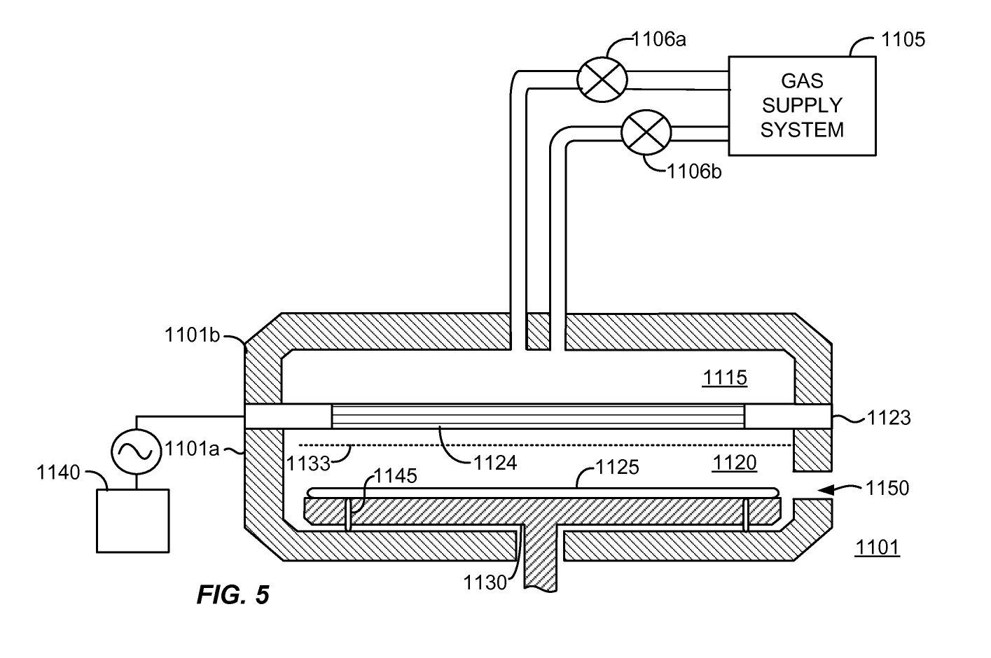

Referring now to FIG. 5, a vertical cross-sectional view of ion implant chamber 1101 is shown and includes chamber body 1101a and chamber lid 1101b. Ion implant chamber 1101 contains a gas supply system 1105 which may provide several precursor through chamber lid 1101b into upper chamber region 1115. The precursors disperse within upper chamber region 1115 and are evenly introduced into substrate processing region 1120 through blocker plate assembly 1123. During substrate processing, substrate processing region 1120 houses substrate 1125 which has been transferred onto substrate pedestal 1130. Substrate pedestal 1130 may provide heat to substrate 1125 during processing to facilitate a implant reaction.

The bottom surface of blocker plate assembly 1123 may be formed from an electrically conducting material in order to serve as an electrode for forming a capacitive plasma. During processing, the substrate (e.g. a semiconductor wafer) is positioned on a flat (or slightly convex) surface of the pedestal 1130. Substrate pedestal 1130 can be moved controllably between a lower loading/off-loading position (depicted in FIG. 5) and an upper processing position (indicated by dashed line 1133). The separation between the dashed line and the bottom surface of blocker plate assembly 1123 is a parameter which helps control the plasma power density during processing.

Before entering upper chamber region 1115, implantation and carrier gases are flowed from gas supply system 1105 through combined or separated delivery lines. Generally, the supply line for each process gas includes (i) several safety shut-off valves 1106 that can be used to automatically or manually shut-off the flow of process gas into the chamber, and (ii) mass flow controllers (not shown) that measure the flow of gas through the supply line.

Once inside upper chamber region 1115, sputtering/implantation and carrier gases are introduced into substrate processing region 1101 through holes in perforated blocker plate (a showerhead) 1124 which forms the lower portion of blocker plate assembly 1123. Inclusion of blocker plate assembly 1123 increases the evenness of the distribution of precursors into substrate processing region 1120.

The implant process performed in ion implant chamber 1101 may be a plasma-based process in embodiments. In a plasma-based process, an RF bias power supply 1140 applies electrical power between perforated blocker plate 1124 and substrate pedestal 1130 to excite the process gas(es). The applied RF bias power forms a plasma within the cylindrical region between perforated blocker plate 1124 and substrate 1125 supported by substrate pedestal 1130. Perforated blocker plate 1124 has either a conducting surface or is insulating with a metal insert. Regardless of position, the metal portion of perforated blocker plate 1124 is electrically isolated from the rest of implant chamber 1101 via dielectric inserts which allow the voltage of perforated blocker plate 1124 to be varied with respect to, especially, substrate pedestal 1130.

Flowing precursors into upper chamber region 1115 and subsequently into substrate processing region 1120 in conjunction with applying RF bias power between faceplate 1124 and substrate pedestal 1130 creates a plasma between faceplate 1124 and substrate 1125. The plasma produces ionized species which are accelerated into a carbon film which may be on the surface of the semiconductor wafer supported on substrate pedestal 1130. RF bias power supply 1140 may be an RF bias power supply that supplies bias power at 13.56 MHz. An RF source power (not shown) may also be used to increase dissociation, if necessary, in substrate processing region 1120. The RF source power may be applied inductively using coils around the perimeter of implant chamber or even around magnetically permeable tubular cores which exit and reenter substrate processing region 1120.

The wafer support platter of substrate pedestal 1130 may be aluminum, anodized aluminum, ceramic, or a combination thereof according to embodiments. The wafer support platter may be resistively heated using an embedded single-loop embedded heater element configured to make two full turns in the form of parallel concentric circles in embodiments. An outer portion of the heater element runs adjacent to a perimeter of the support platter, while an inner portion runs on the path of a concentric circle having a smaller radius. The wiring to the heater element passes through the stem of substrate pedestal 1130.

A lift mechanism and motor raises and lowers the substrate pedestal 1130 and wafer lift pins 1145 as wafers are transferred into and out of substrate processing region 1120 by a robot blade (not shown) through an insertion/removal opening 1150 in the side of chamber body 1101a. The motor raises and lowers substrate pedestal 1130 between a processing position 1133 and a lower, wafer-loading position.

Substrate processing system 1001 is controlled by a system controller. In an exemplary embodiment, the system controller includes storage media and processors (e.g. general purpose microprocessors or application specific IC's). The processors may be processor cores present on a monolithic integrated circuit, separated but still located on a single-board computer (SBC) or located on separate printed circuit cards possibly located at multiple locations about the substrate processing system. The processors communicate with one another as well as with analog and digital input/output boards, interface boards and stepper motor controller boards using standard communication protocols.

The system controller controls all of the activities of substrate processing system 1001 including implant chamber 1101. The system controller executes system control software, which is a computer program stored in a computer-readable medium. Preferably, the medium is a hard disk drive, but the medium may also be other kinds of memory. The computer program includes sets of instructions that dictate the timing, mixture of gases, chamber pressure, chamber and substrate temperatures. RF power levels, support pedestal position, and other parameters of a particular process.

A process for implanting a carbon film on a substrate can be implemented using a computer program product that is executed by the system controller. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled library routines. To execute the linked, compiled object code the system user invokes the object code, causing the computer system to load the code in memory. The CPU then reads and executes the code to perform the tasks identified in the program.

The interface between a user and the controller is via a flat-panel touch-sensitive monitor. In the preferred embodiment two monitors are used, one mounted in the clean room wall for the operators and the other behind the wall for the service technicians. The two monitors may simultaneously display the same information, in which case only one accepts input at a time. To select a particular screen or function, the operator touches a designated area of the touch-sensitive monitor. The touched area changes its highlighted color, or a new menu or screen is displayed, confirming communication between the operator and the touch-sensitive monitor. Other devices, such as a keyboard, mouse, or other pointing or communication device, may be used instead of or in addition to the touch-sensitive monitor to allow the user to communicate with the system controller.

As used herein “substrate” may be a support substrate with or without layers formed thereon. The support substrate may be an insulator or a semiconductor of a variety of doping concentrations and profiles and may, for example, be a semiconductor substrate of the type used in the manufacture of integrated circuits. A carbon film may comprise or consist of carbon and hydrogen. A gas in an “excited state” describes a gas wherein at least some of the gas molecules are in vibrationally-excited, dissociated and/or ionized states. A gas may be a combination of two or more gases. The term “precursor” is used to refer to any process gas which takes part in a reaction to either remove, deposit or modify material on a surface.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the precursor” includes reference to one or more precursor and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

We claim:

1. A method of treating a carbon film on a semiconductor substrate, the method comprising:
transferring the semiconductor substrate onto a substrate pedestal in a substrate processing region;
flowing an inert gas into the substrate processing region;
applying capacitive power between the substrate pedestal and a parallel conducting plate;
forming a plasma from the inert gas within the substrate processing region; and
sputtering the carbon film to form a reduced-stress carbon film.

2. The method of claim 1, wherein the reduced-stress carbon film comprises more than 25% sp³ carbon bonding.

3. The method of claim 1, wherein the substrate processing region is essentially devoid of reactive species and consists of inert gases.

4. The method of claim 1, wherein the inert gas comprises one or both of helium and argon.

5. The method of claim 1, wherein the reduced-stress carbon film consists of carbon and hydrogen.

6. A method of treating a carbon film on a semiconductor substrate, the method comprising:
transferring the semiconductor substrate onto a substrate pedestal in a substrate processing region;
flowing a carbon-and-hydrogen-containing precursor into the substrate processing region;
applying capacitive power between the substrate pedestal and a parallel conducting plate;
forming a plasma from the carbon-and-hydrogen-containing precursor within the substrate processing region; and
implanting the carbon film to form a reduced-stress carbon film.

7. The method of claim 6, wherein the reduced-stress carbon film remains diamond-like carbon following the operation of implanting the carbon film.

8. The method of claim 6, wherein the substrate processing region is essentially devoid of reactive species other than the carbon-and-hydrogen-containing precursor.

9. The method of claim 6, wherein the carbon-and-hydrogen-containing precursor consists of carbon and hydrogen.

10. The method of claim 6, wherein the reduced-stress carbon film consists of carbon and hydrogen.

11. A method of treating a carbon film on a semiconductor substrate, the method comprising:
transferring the semiconductor substrate onto a substrate pedestal in a substrate processing region;
flowing a nitrogen-containing precursor into the substrate processing region;
applying capacitive power between the substrate pedestal and a parallel conducting plate;
forming a plasma from the nitrogen-containing precursor within the substrate processing region to form plasma effluents; and
implanting the carbon film with the plasma effluents to form a reduced-stress carbon film.

12. The method of claim 10, wherein the reduced-stress carbon film comprises more than 25% sp³ carbon bonding.

13. The method of claim 10, wherein the substrate processing region is essentially devoid of reactive species other than the nitrogen-containing precursor.

14. The method of claim 10, wherein the nitrogen-containing precursor comprises one or both of diatomic nitrogen (N₂), hydrazine, and ammonia (NH₃).

15. The method of claim 10, wherein the reduced-stress carbon film consists of carbon, nitrogen and hydrogen.
